(19) United States
(12) Patent Application Publication
(10) Pub. No.: US 2025/0087500 A1
(43) Pub. Date: Mar. 13, 2025

(54) METHOD FOR PREPARING FCBGA PACKAGE SUBSTRATE

(71) Applicant: Shanghai Meadville Science & Technology Co., Ltd, Shanghai (CN)

(72) Inventors: Wei YANG, Shanghai (CN); Wenlong XU, Shanghai (CN); Lingling DU, Shanghai (CN); Aidong ZHUANG, Shanghai (CN); Jingyong SONG, Shanghai (CN); Haitao FU, Shanghai (CN); Xiaogang ZHA, Shanghai (CN)

(73) Assignee: Shanghai Meadville Science & Technology Co., Ltd, Shanghai (CN)

(21) Appl. No.: 18/716,154

(22) PCT Filed: Sep. 21, 2022
(86) PCT No.: PCT/CN2022/120239

§ 371 Date: Jun. 4, 2024

(30) Foreign Application Priority Data
Jun. 1, 2022 (CN) 2022106229771

(51) Int. Cl. H01L 21/48; H01L 23/498

(52) U.S. Cl. CPC H01L 21/486; H01L 21/4853; H01L 23/49838; H01L 23/49894

(57) ABSTRACT

A method for preparing FCBGA package substrate can effectively reduce the size of the connecting hole by using the inductively coupled plasma etching, where the connecting hole having minimum width of 40 μm or less can be manufactured, and multiple connecting holes having different sizes and/or different shapes can be formed at one time, which can effectively reduce the cost and increase the wiring-density of the FCBGA package substrate. The inductively coupled plasma etching applied to the build-up layer is a chemical reaction, which can avoid the problems of black edges and heat-affected zones caused by thermal ablation and form a metal connecting layer with good adhesion without slag removal, therefore, the present disclosure can prepare the FCBGA package substrate with good reliability and electrical performance by utilizing the inductively coupled plasma etching.

### TECHNICAL FIELD

The present disclosure relates to the technical field of integrated circuit fabrication, and in particular, to a method for preparing FCBGA package substrate.

### BACKGROUND OF THE INVENTION

Flip Chip Ball Grid Array (FCBGA) is currently the main method for packaging high-level chips. As the integration level of electronic products and the pattern density on the FCBGA package substrate is getting higher and higher, more blind holes with smaller sizes or grooves with various sizes and shapes are required according to the product requirements.

At present, the main method for mass production of blind holes and grooves is to use a UV laser drilling machine or a CO₂ laser drilling machine to drill blind holes or mill grooves on the FCBGA package substrate. However, the limitations of laser drilling mainly include the following:

On the one hand, the cost of the laser drilling machine is very high. As the number of blind holes on the substrate increases substantially, so does the cost of laser drilling. For example, to ensure the high-density wiring layout of the product, a large number of blind holes are designed on the FCBGA package substrate, i.e. the number of blind holes increases continuously, resulting in a significant increase in the cost of laser drilling.

On the other hand, UV laser is a high-energy laser beam and most of the laser energy is used for photochemical effect when drilling, which belongs to photochemical cracking and etching. Due to the high energy of UV laser, it can directly cut metals and glasses, and is suitable for small aperture processing. However, accurate control of the laser drilling parameters is necessary, otherwise, the bottom of the blind hole would be easily burned through. CO₂ laser drilling has a working wavelength of 9300 to 10600 nm, and the CO₂ laser absorption rates of the copper layer of the copper clad laminate and the dielectric layer are different, therefore, the CO₂ laser can only form holes in the dielectric layer with the copper layer at the bottom not easily to be damaged, which enables CO₂ laser drilling to become an important method for producing blind holes. The basic principle of CO₂ laser drilling is that the processed material absorbs the low-energy laser, so that the organic plate is melted or vaporized with strong heat in a very short time and then blind holes can be formed with such continuous removal. CO₂ laser drilling includes the interaction of the laser and the processed material (specifically including the following different energy conversion processes: reflection, absorption, vaporization, re-radiation, and heat diffusion) and belongs to photothermal ablation. It has been found that CO₂ laser drilling in practice tends to cause excessive carbonization on the product surface and even scorches the board surface, which is prone to leave glue residue, thus affecting the electrical performance of the product.

Furthermore, the laser light source is a very powerful and highly directional electromagnetic wave whose wavelength is mostly in the range of ultraviolet, visible light, and infrared. The time of laser beam irradiation or laser pulse is controlled in a limited range. When a powerful laser beam reaches the surface of a substance, the electrons in the substance will absorb the electromagnetic waves and accelerate their movements, then collide violently with other electrons or ions, where these collisions generate heat quickly until the area irradiated by the beam is melted, vaporized and ionized, thereby forming holes. During the above-mentioned collision and melting processes, if the laser beam irradiation or laser pulse takes too long, i.e., if the collision time of these laser pulses is long or the number of laser shocking is less than 1 million times per second, a lot of energy is conducted and diffused to the surrounding area, thus forming a “heat-affected zone” (HAZ) whose thickness ranges from tens of microns to hundreds of microns. In addition, thermal damage or destruction, such as melting, deformation, wrinkling, roughness, cracking, or delamination will occur at the interface of this “heat-affected zone” and the surrounding area.

Therefore, it is necessary to provide a method for preparing FCBGA package substrate to effectively solve the quality and cost problems of producing blind holes or grooves on the FCBGA package substrate.

### SUMMARY OF THE INVENTION

The present disclosure provides a method for preparing FCBGA package substrate, to solve the problem of producing the FCBGA package substrate in the prior art.

The present disclosure provides a method for preparing FCBGA package substrate, which includes: providing a core plate, where the core plate includes a dielectric layer and first copper foil layers located on two opposite sides of the dielectric layer; forming an interconnecting hole penetrating the core plate; forming an interconnecting conductive layer covering the interconnecting hole and the first copper foil layers; patterning the interconnecting conductive layer and the first copper foil layers to expose the dielectric layer to form a core layer structure; forming a build-up layer and a second copper foil layer on each of two opposite sides of the core layer structure using a laminating method, where the build-up layer is arranged on the core layer structure, and the second copper foil layer is arranged on the build-up layer; patterning the second copper foil layers to form an etching window; performing inductively coupled plasma etching in the etching windows to form a connecting hole penetrating the build-up layers; removing the second copper foil layers; and forming a patterned metal connecting layer in the connecting hole, the patterned metal connecting layer is electrically connected to the core layer structure, where the metal connecting layer includes a seed layer and a metal layer.

Optionally, a shape of the connecting hole includes one or more of a circle, an ellipse, and a polygon.

Optionally, the width of the connecting hole has a minimum size of 40 μm or less.

Optionally, the build-up layer may be made of ABF or PP.

Optionally, the inductively coupled plasma etching is performed by using a mixed gas of carbon tetrafluoride and oxygen. A radio frequency bias voltage of the inductively coupled plasma etching ranges from 10V to 30V, and an etching time of the inductively coupled plasma etching ranges from 80 min to 120 min.

Optionally, the seed layer includes a copper seed layer formed by chemical plating or a titanium/copper stacked seed layer formed by sputtering.

Optionally, forming the metal layer includes the following steps: laminating, exposing, developing, electroplating, striping, and etching.

Optionally, a method for forming the interconnecting hole includes mechanical drilling or laser drilling.

Optionally, the interconnecting hole is filled up with the interconnecting conductive layer; or the interconnecting conductive layer covers only sidewalls of the interconnecting hole, and a remaining part of the interconnecting hole is filled up with an insulating layer.

Optionally, the steps after forming the core layer structure can be repeated until the required number of stacked layers for the preparation of a multi-layer FCBGA package substrate is formed.

As described above, it can be seen that the method for preparing FCBGA package substrate of the present disclosure can effectively reduce the size of the connecting hole by adopting the inductively coupled plasma etching, where the connecting hole having a minimum width of 40 μm or less can be manufactured, and multiple connecting holes having different sizes and/or different shapes can be formed at one time, which can effectively reduce the cost and increase the wiring-density of the FCBGA package substrate. The inductively coupled plasma etching applied to the build-up layer is a chemical reaction, which can avoid the problems of black edges and heat-affected zones caused by thermal ablation and can form a metal connecting layer with good adhesion without slag removal, therefore, the present disclosure can prepare the FCBGA package substrate with good reliability and electrical performance based on the inductively coupled plasma etching.

### BRIEF DESCRIPTION OF DRAWINGS

FIG. 1 shows a process flow chart of preparing a FCBGA package substrate by using the inductive coupling plasma etching of the present disclosure.

FIG. 2 shows a schematic diagram of a core plate according to an embodiment of the present disclosure.

FIG. 3 shows a schematic diagram of forming an interconnecting hole according to an embodiment of the present disclosure.

FIG. 4a shows a schematic diagram of forming an interconnecting conductive layer according to an embodiment of the present disclosure.

FIG. 4b shows another schematic diagram of forming an interconnecting conductive layer according to an embodiment of the present disclosure.

FIG. 5 shows a schematic diagram of forming a core layer structure according to an embodiment of the present disclosure.

FIG. 6 shows a schematic diagram of forming a build-up layer and a second copper foil layer according to an embodiment of the present disclosure.

FIG. 7 shows a schematic diagram of forming an etching window according to an embodiment of the present disclosure.

FIG. 8 shows a schematic diagram of forming a connecting hole by inductively coupled plasma etching according to an embodiment of the present disclosure.

FIG. 9 shows a schematic diagram of removing the second copper foil layer according to an embodiment of the present disclosure.

FIG. 10a shows a schematic diagram of forming a metal connecting layer according to an embodiment of the present disclosure.

FIG. 10b shows another schematic diagram of forming a metal connecting layer according to an embodiment of the present disclosure.

### REFERENCE NUMERALS

100—core layer structure;
101—dielectric layer;
102—first copper foil layer;
103—interconnecting hole;
104—copper seed layer of interconnecting conductive layer;
105—copper metal layer of interconnecting conductive layer;
106—insulating layer;
201—build-up layer;
202—second copper foil layer;
203—etching window;
204—connecting hole;
205—copper seed layer of metal connecting layer
206—copper metal layer of metal connecting layer;
207—titanium seed layer of metal connecting layer;
S1 to S9—steps.

### DETAILED DESCRIPTION OF THE INVENTION

The embodiments of the present disclosure will be described below through specific examples. Those skilled in the art can easily understand other advantages and effects of the present disclosure according to the contents disclosed by the specification. The present disclosure may also be implemented or applied through other different specific implementation modes. Various modifications or changes may be made to all details in the specification based on different points of view and applications without departing from the spirit of the present disclosure.

When describing the embodiments of the present disclosure, the cross-sectional view showing the structure of the device will not be partially enlarged to the general scale for convenience of description, and the schematic diagrams are only examples, which should not be regarded as limitations to the protection scope of the present disclosure. In addition, three-dimensional spatial dimensions of length, width, and depth should be included in the actual production.

For ease of description, spatial words such as “below”, “under”, “lower”, “beneath”, “on”, “above”, and the like may be used herein to describe the relationship of one shown element or feature to other elements or features in the drawings. It should be understood that these spatial relationship words are intended to include other directions of the device in use or operation, in addition to the directions depicted in the drawings. Further, when a layer is referred to as being “between” two layers, it may be the only layer between the two layers, or there may be one or more layers between the two layers. The “range from . . . to . . . ” used herein includes two endpoint values.

In the context of the present disclosure, the described structure of the first feature being “above” the second feature may include embodiments in which the first and second features are in direct contact, and may also include embodiments in which additional features are formed between the first and second features, such that the first and second features may not be in direct contact.

It needs to be stated that the drawings provided in the following embodiments are just used for schematically describing the basic concept of the present disclosure, thus only illustrating components related to the present disclosure and are not drawn according to the numbers, shapes, and sizes of components during actual implementation, the configuration, number and scale of each component during the actual implementation thereof may be freely changed, and the component layout configuration thereof may be more complicated.

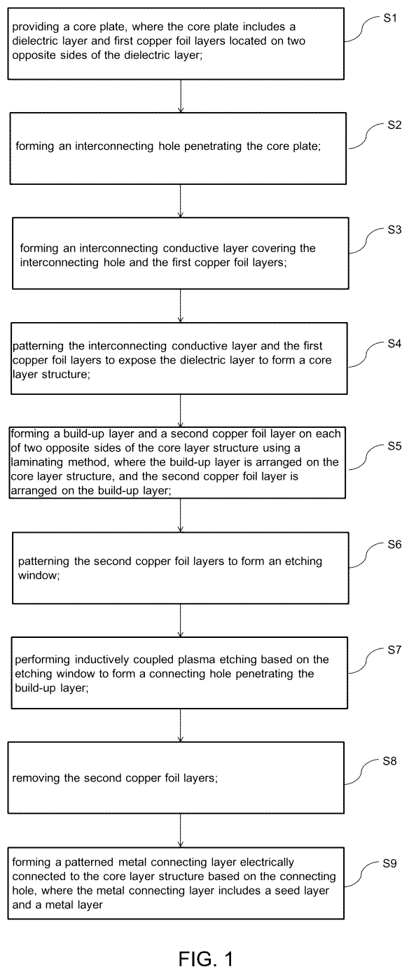

As shown in FIG. 1, the present disclosure provides a method for preparing FCBGA package substrate, which includes:
S1: providing a core plate, where the core plate includes a dielectric layer and first copper foil layers located on two opposite sides of the dielectric layer;
S2: forming an interconnecting hole penetrating the core plate;
S3: forming an interconnecting conductive layer covering the interconnecting hole and the first copper foil layers;
S4: patterning the interconnecting conductive layer and the first copper foil layers to expose the dielectric layer to form a core layer structure;
S5: forming build-up layers and second copper foil layers on two opposite sides of the core layer structure using a laminating method, where each of the build-up layers is arranged on the core layer structure, and each of the second copper foil layers is arranged on the build-up layer;
S6: patterning the second copper foil layers to form etching windows;
S7: performing inductively coupled plasma etching in the etching windows to form connecting holes penetrating the build-up layers;
S8: removing the second copper foil layers; and
S9: forming a patterned metal connecting layer in the connecting hole, the patterned metal connecting layer is electrically connected to the core layer structure, where the metal connecting layer includes a seed layer and a metal layer.

The method for preparing FCBGA package substrate of this embodiment can improve production efficiency and reduce the size of the connecting hole effectively by adopting the inductively coupled plasma etching, where two sides of the substrate can be processed simultaneously and multiple connecting holes having different sizes and/or different shapes can be formed at one time, which can effectively reduce the cost and increase the wiring-density of the FCBGA package substrate. The inductively coupled plasma etching applied to the build-up layer is a chemical reaction, which can avoid the problems of black edges and heat-affected zones caused by thermal ablation and can form a metal connecting layer with good adhesion without slag removal, therefore, the present disclosure can prepare the FCBGA package substrate with good reliability and electrical performance by using the inductively coupled plasma etching.

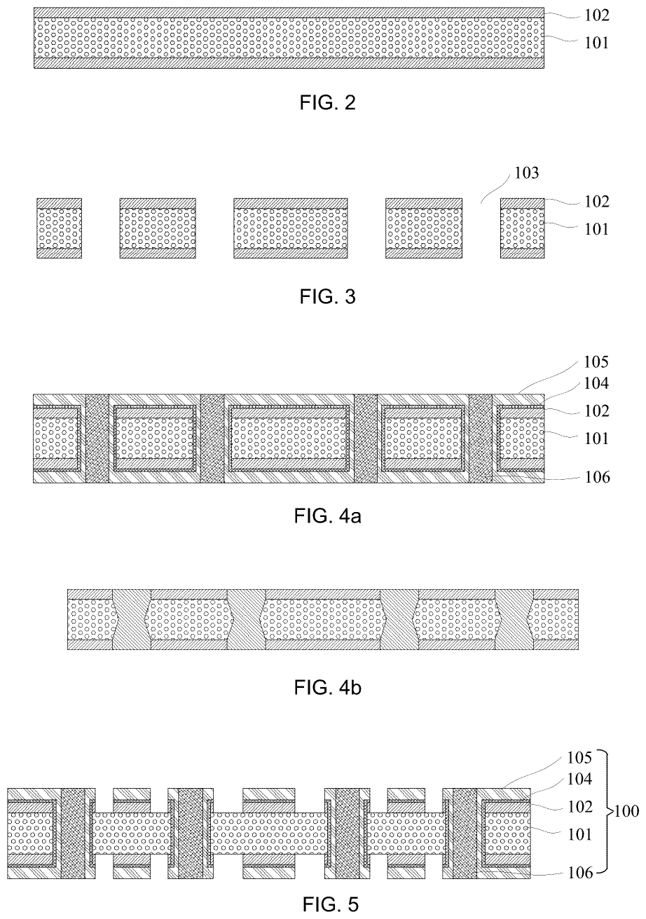

The method for preparing FCBGA package substrate is further described in combination with FIGS. 2 to 10b.

As shown in FIG. 2, step S1 is performed to provide a core plate including a dielectric layer 101 and first copper foil layers 102 located on two opposite sides of the dielectric layer 101.

Specifically, the core plate is a three-layer structure in which a first copper foil layer 102, the dielectric layer 101, and another first copper foil layer 102 are sequentially stacked, i.e., two first copper foil layers 102 are provided and are respectively disposed on a first side of the dielectric layer 101 and a second side the dielectric layer 101, where the second side is opposite to the first side. The dielectric layer 101 can be made of an insulating material with a glass transition temperature of 260° C. and a deformation amount in XY direction of less than 10 ppm/° C. or 6 ppm/° C. The thickness of the first copper foil layer 102 can be 12 μm. However, the structure of the core plate is not limited to the above examples.

As shown in FIG. 3, step S2 is performed to form an interconnecting hole 103 penetrating the core plate.

Specifically, mechanical drilling or laser drilling can be utilized for the fabricating of the interconnecting hole 103. A mechanical drilling machine can be used for mechanical drilling, and the formed interconnecting hole with a diameter of 150 μm is shown in FIG. 3. However, mechanical drilling is not limited to the above examples. The laser drilling may be performed on both sides of the core plate by using a laser drilling machine, and the formed interconnecting hole has a diameter ranging from 40 μm to 200 μm, such as 40 μm, 50 μm, 150 μm, 200 μm, etc.

As shown in FIGS. 4a and 4b, step S3 is performed to form an interconnecting conductive layer covering the interconnecting hole 103 and the first copper foil layers 102. The interconnecting conductive layer includes a copper seed layer 104 and a copper metal layer 105. As an example, the copper seed layer 104 of the interconnecting conductive layer is covered by the copper metal layer 105 of the interconnecting conductive layer.

Specifically, after mechanical drilling or laser drilling, the glue residue on the core plate is removed to improve the bonding force between the interconnecting conductive layer and the core plate, and then a copper seed layer 104 of the interconnecting conductive layer is first formed by chemical plating, later a copper metal layer 105 of the interconnecting conductive layer is formed by electroplating to complete the fabrication of the interconnecting conductive layer.

As an example, the interconnecting hole 103 may be filled up with the formed interconnecting conductive layer, which is shown in FIG. 4b, or the formed interconnecting conductive layer covers only the sidewalls of the interconnecting hole 103, and the remaining part of the interconnecting hole 103 is filled up with the insulating layer 106, which is shown in FIG. 4a.

Specifically, the diameter of the interconnecting hole 103 formed by the laser drilling is smaller than the diameter of the interconnecting hole 103 formed by the mechanical drilling. In addition, the interconnecting hole 103 is filled up with the insulating layer 106 to further improve the mechanical stability thereof. In this embodiment, mechanical drilling is used to form the interconnecting hole 103, the interconnecting conductive layer covers only the sidewalls of the interconnecting hole 103, and the remaining part of the interconnecting hole 103 is filled up with the insulating layer 106, where the insulating layer 106 is made of resin, however, the material of the insulating layer is not limited thereto. In another embodiment, laser drilling can be used to prepare the interconnecting hole 103 with a small diameter, then the interconnecting hole 103 can be filled up only with the formed interconnecting conductive layer, which is shown in FIG. 4b. And the method for forming the interconnecting conductive layer can be selected according to actual needs, therefore, excessive limitations will not be set herein.

As shown in FIG. 5, step S4 is performed to pattern the interconnecting conductive layer and the first copper foil layers 102 to expose the dielectric layer 101 to form a core layer structure 100.

Specifically, the method for patterning the interconnecting conductive layer and the first copper foil layers 102 may include laminating, exposing, developing, forming etching windows, then performing etching on the interconnecting conductive layer and the first copper foil layers, and finally performing a dry striping to form the core layer structure 100. The size and layout of the etching windows can be designed as desired, therefore, there are no undue restrictions herein. As an example, the core layer structure 100 includes the dielectric layer 101, the first copper foil layers 102, the interconnecting conductive layer, and the insulting layer 106.

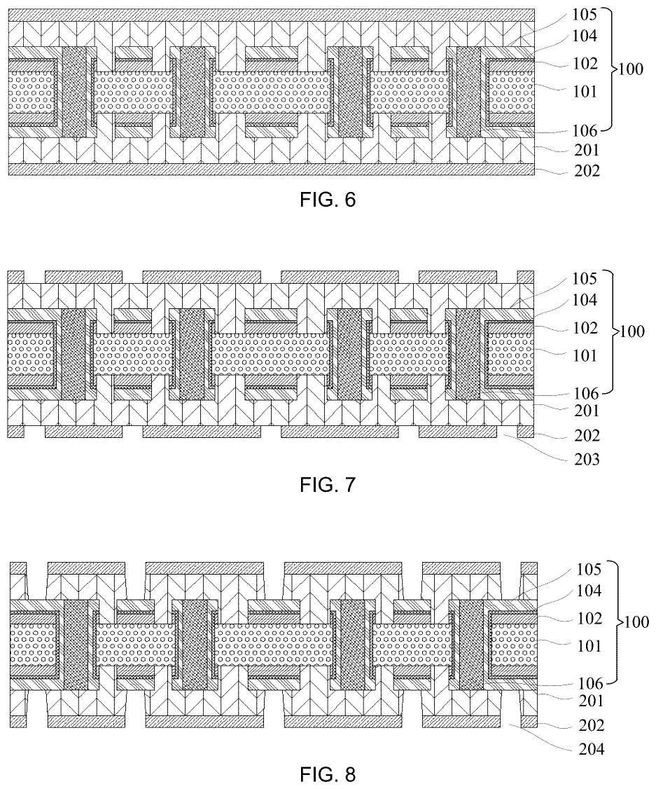

As shown in FIG. 6, step S5 is performed to form build-up layers 201 and second copper foil layers 202 on two opposite sides of the core layer structure 100 by adopting a laminating method, where the build-up layer is arranged on the core layer structure, and the second copper foil layer is arranged on the build-up layer.

Optionally, the build-up layer may be made of ABF or PP.

Specifically, the build-up layer 201 may be made of ABF material containing silicon oxide and epoxy resin, or PP material containing glass fiber and epoxy resin, etc. The types of the build-up layer 201 and the second copper foil layer 202 may be selected according to specific needs, therefore, no excessive limitations are set herein. The laminating method can be a vacuum laminating method, so that the build-up layers 201 and the second copper foil layers 202 with good bonding forces can be formed on the opposite sides of the core layer structure 100 along the direction from inside to outside. The thicknesses of the build-up layer 201 and the second copper foil layer 202 are not excessively limited herein.

As shown in FIG. 7, step S6 is performed to pattern the second copper foil layers 202 to form etching windows 203.

Specifically, the etching windows 203 can be formed on the second copper foil layers 202 by the steps of laminating, exposing, developing, etching, and striping, so that the build-up layer 201 can be patterned based on the etching windows 203.

As shown in FIG. 8, step 7 is performed to form a connecting hole 204 penetrating the build-up layer 201 by performing inductively coupled plasma etching on the etching windows 203.

Specifically, the inductively coupled plasma etching can be carried out by using a mixed gas of carbon tetrafluoride and oxygen. The radio frequency bias voltage of the inductively coupled plasma etching ranges from 10V to 30V, such as 10V, 15V, 20V, 30V, etc., and the etching time ranges from 80 min to 120 min, such as 80 min, 100 min, 120 min, etc. Multiple times of the inductively coupled plasma etching may be performed according to the thickness of the build-up layer 201 to form the connecting hole 204 penetrating the build-up layer 201.

The shape of the connecting hole 204 may include one or more of a circle, an ellipse, and a polygon, such as a circle, a square, a trapezoid, etc. and the minimum width of the connecting hole 204 may be 40 μm or less, such as 40 μm, 30 μm, 20 μm, etc. A plurality of connecting holes 204 with different sizes and/or different shapes can be formed at one time, such as small blind holes, large blind holes, small grooves, large grooves, and the like, thus effectively reducing the cost and improving the wiring density.

Furthermore, since the inductively coupled plasma etching applied to the build-up layer 201 is a chemical reaction, the problem of the edge blackening and the formation of the heat-affected zone caused by thermal ablation can be avoided when preparing the connecting hole 204.

As shown in FIG. 9, step S8 is performed to remove the second copper foil layers 202 to expose the build-up layers 201, where the second copper foil layers 202 can be etched for removal.

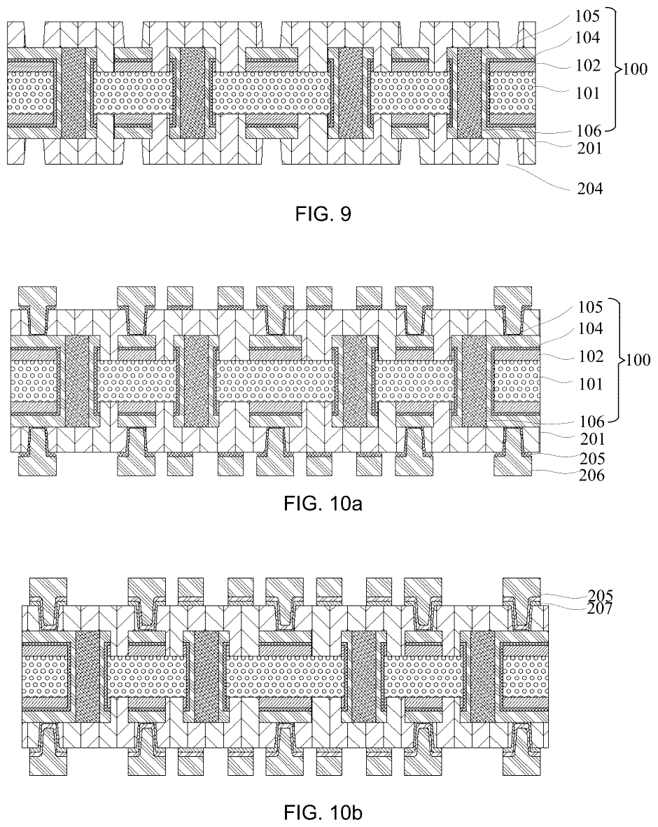

As shown in FIGS. 10a and 10b, step S9 is performed based on the connecting hole 204 to form a patterned metal connecting layer that is electrically connected to the core layer structure 100, where the metal connecting layer includes a seed layer and a metal layer.

As an example, the seed layer includes a copper seed layer 205 formed by chemical plating or a titanium-copper stacked seed layer formed by sputtering.

Specifically, as shown in FIG. 10a, the seed layer in this embodiment is the copper seed layer 205 formed by chemical plating, however, the seed layer is not limited to the above example. As shown in FIG. 10b, in another embodiment, in order to further improve the bonding force between the metal connecting layer and the core layer structure 100, the titanium-copper stacked seed layer formed by sputtering can be used which includes the titanium seed layer 207 and the copper seed layer 205. The seed layer can be selected according to requirements. In this embodiment, when etching the build-up layer 201, the glue residue caused by ablation can be avoided by utilizing the inductively coupled plasma etching, so that the removal of the glue slag before forming the seed layer can be omitted, thus simplifying the process flow and reducing the cost.

The copper metal layer 206 having a relatively small size can be formed on the seed layer by the operations of laminating, exposing, developing, electroplating, striping, and etching.

As an example, the steps after forming the core layer structure 100 can be repeated until the required number of stacked layers for the preparation of a multi-layer FCBGA package substrate is formed.

Specifically, the above steps S5 to S9 can be repeated until the required number of stacked layers (such as 2 layers, 4 layers, 6 layers, etc.) for the formation of a multi-layer FCBGA package substrate are prepared, and the specific number of stacked layers is not excessively limited herein.

In conclusion, the method for preparing FCBGA package substrate of the present disclosure can effectively reduce the size of the connecting hole by using the inductively coupled plasma etching, where the connecting hole having a minimum width of 40 μm or less can be manufactured, and multiple connecting holes having different sizes and/or different shapes can be formed at one time, which can effectively reduce the cost and increase the wiring-density of the FCBGA package substrate. The inductively coupled plasma etching applied to the build-up layer is a chemical reaction, which can avoid the problems of black edges and heat-affected zones caused by thermal ablation and can form a metal connecting layer with good adhesion without slag removal, therefore, the present disclosure can prepare the FCBGA package substrate with good reliability and electrical performance by employing the inductively coupled plasma etching.

The above-mentioned embodiments are just used for exemplarily describing the principle and effects of the present disclosure instead of limiting the present invention. Those skilled in the art can make modifications or changes to the above-mentioned embodiments without going against the spirit and the range of the present disclosure. Therefore, all equivalent modifications or changes made by those who have common knowledge of the art without departing from the spirit and technical concept disclosed by the present disclosure shall be still covered by the claims of the present disclosure.

1. A method for preparing FCBGA (Flip Chip Ball Grid Array) package substrate, comprising:
providing a core plate, wherein the core plate includes a dielectric layer and first copper foil layers located on two opposite sides of the dielectric layer;
forming an interconnecting hole penetrating the core plate;
forming an interconnecting conductive layer covering the interconnecting hole and the first copper foil layers;
patterning the interconnecting conductive layer and the first copper foil layers to expose the dielectric layer to form a core layer structure;
forming a build-up layer and a second copper foil layer on each of two opposite sides of the core layer structure using a laminating method, wherein the build-up layer is arranged on the core layer structure, and the second copper foil layer is arranged on the build-up layer;
patterning the second copper foil layers to form an etching window;
performing inductively coupled plasma etching based on the etching window to form a connecting hole penetrating the build-up layer;
removing the second copper foil layers; and
forming a patterned metal connecting layer electrically connected to the core layer structure based on the connecting hole, wherein the metal connecting layer includes a seed layer and a metal layer.

2. The method for preparing FCBGA package substrate according to claim 1, wherein a shape of the connecting hole includes one or more of a circle, an ellipse, and a polygon.

3. The method for preparing FCBGA package substrate according to claim 1, wherein the connecting hole has a minimum width of 40 μm or less.

4. The method for preparing FCBGA package substrate according to claim 1, wherein the build-up layer is made of ABF or PP.

5. The method for preparing FCBGA package substrate according to claim 4, wherein the build-up layer is made of ABF material containing silicon oxide and epoxy resin, or PP material containing glass fiber and epoxy resin.

6. The method for preparing FCBGA package substrate according to claim 1, wherein the laminating method is a vacuum laminating method.

7. The method for preparing FCBGA package substrate according to claim 1, wherein the inductively coupled plasma etching is carried out by using a mixed gas of carbon tetrafluoride and oxygen; wherein a radio frequency bias voltage of the inductively coupled plasma etching ranges from 10V to 30V, and an etching time of the inductively coupled plasma etching ranges from 80 min to 120 min.

8. The method for preparing FCBGA package substrate according to claim 1, wherein the seed layer includes a copper seed layer formed by chemical plating or a titanium/copper stacked seed layer formed by sputtering.

9. The method for preparing FCBGA package substrate according to claim 1, wherein the forming of the metal layer includes the following: laminating, exposing, developing, electroplating, striping, and etching.

10. The method for preparing FCBGA package substrate according to claim 1, wherein a method for forming the interconnecting hole includes mechanical drilling or laser drilling.

11. The method for preparing FCBGA package substrate according to claim 1, wherein the interconnecting conductive layer includes a copper seed layer of interconnecting conductive layer and a copper metal layer of interconnecting conductive layer.

12. The method for preparing FCBGA package substrate according to claim 11, wherein the forming of the interconnecting conductive layer covering the interconnecting hole and the first copper foil layers includes:
removing glue residue on the core plate;
forming the copper seed layer of interconnecting conductive layer by using chemical plating; and
forming the copper metal layer of interconnecting conductive layer by using electroplating.

13. The method for preparing FCBGA package substrate according to claim 1, wherein the interconnecting hole is filled up with the interconnecting conductive layer; or the interconnecting conductive layer covers only sidewalls of the interconnecting hole, and a remaining part of the interconnecting hole is filled up with an insulating layer.

14. The method for preparing FCBGA package substrate according to claim 1, wherein the steps after forming the core layer structure are repeated until a required number of stacked layers for the preparation of a multi-layer FCBGA package substrate is formed.

15. A FCBGA package substrate prepared from the method according to claim 1.
